(19) United States
(12) Patent Application Publication
(10) Pub. No.: US 2017/0323872 A1
(43) Pub. Date: Nov. 9, 2017

(54) OPTOELECTRONIC COMPONENT AND METHOD OF PRODUCING SAME

(71) Applicant: OSRAM Opto Semiconductors GmbH, Regensburg (DE)

(72) Inventors: Frank Singer, Regenstauf (DE); Jürgen Moosburger, Lappersdorf (DE); Matthias Sabathil, Regensburg (DE); Matthias Sperl, Mintraching (DE); Björn Hoxhold, Sinzing Viehhausen (DE)

(21) Appl. No.: 15/523,812

(22) PCT Filed: Nov. 3, 2015
(86) PCT No.: PCT/EP2015/075517

§ 371 Date: May 2, 2017

(30) Foreign Application Priority Data
Nov. 4, 2014 (DE) 10 2014 116 079.7

(51) Int. Cl. H01L 25/16; H01L 33/48; H01L 33/54; H01L 33/62; H01L 33/50

(52) U.S. Cl. CPC H01L 25/167; H01L 33/62; H01L 33/507; H01L 33/54; H01L 33/483; H01L 2933/0041; H01L 2933/005; H01L 2933/0066

(57) ABSTRACT

An optoelectronic component includes a composite body including a molded body; and an optoelectronic semiconductor chip embedded into the molded body, wherein an electrically conductive through contact extends from a top side of the composite body to an underside of the composite body through the molded body, a top side of the optoelectronic semiconductor chip is at least partly not covered by the molded body, the chip includes a first electrical contact on its top side, a first top side metallization is arranged on the top side of the composite body and electrically conductively connects the first electrical contact to the through contact, the optoelectronic component includes an upper insulation layer extending over the first top side metallization, and the optoelectronic component includes a second top side metallization arranged above the upper insulation layer and electrically insulated with respect to the first top side metallization by the upper insulation layer.

### TECHNICAL FIELD

This disclosure relates to an optoelectronic component and a method of producing an optoelectronic component.

### BACKGROUND

Optoelectronic components, for example, light emitting diode components, are known with different housing variants. By way of example, optoelectronic components are known in which an optoelectronic semiconductor chip is embedded into a molded body that forms a supporting housing element. Such optoelectronic components comprise very compact external dimensions.

### SUMMARY

We provide an optoelectronic component including a composite body including a molded body; and an optoelectronic semiconductor chip embedded into the molded body, wherein an electrically conductive through contact extends from a top side of the composite body to an underside of the composite body through the molded body, a top side of the optoelectronic semiconductor chip is at least partly not covered by the molded body, the optoelectronic semiconductor chip includes a first electrical contact on its top side, a first top side metallization is arranged on the top side of the composite body and electrically conductively connects the first electrical contact to the through contact, the optoelectronic component includes an upper insulation layer extending over the first top side metallization, and the optoelectronic component includes a second top side metallization arranged above the upper insulation layer and electrically insulated with respect to the first top side metallization by the upper insulation layer.

We also provide a method of producing an optoelectronic component including providing an optoelectronic semiconductor chip including a first electrical contact on a top side; embedding the optoelectronic semiconductor chip into a molded body to form a composite body, wherein the top side of the optoelectronic semiconductor chip is at least partly not covered by the molded body; establishing an electrically conductive through contact extending from a top side of the composite body to an underside of the composite body through the molded body; establishing a first top side metallization on the top side of the composite body, the first top side metallization electrically conductively connecting the first electrical contact to the through contact; establishing an upper insulation layer extending over the first top side metallization; and establishing a second top side metallization above the upper insulation layer, the second top side metallization being electrically insulated with respect to the first top side metallization by the upper insulation layer.

### BRIEF DESCRIPTION OF THE DRAWINGS

FIG. 1 schematically shows a plan view of a first optoelectronic component.

FIG. 2 schematically shows a sectional side view of the first optoelectronic component.

FIG. 3 schematically shows a plan view of a second optoelectronic component.

FIG. 4 schematically shows a sectional side view of a third optoelectronic component.

### LIST OF REFERENCE SIGNS

10 first optoelectronic component
20 second optoelectronic component
30 third optoelectronic component
100 composite body
101 top side
102 underside
110 first top side metallization
120 second top side metallization
130 first underside metallization
140 second underside metallization
150 lower insulation layer
160 upper insulation layer
170 delimited region
200 molded body
201 top side
202 underside
300 optoelectronic semiconductor chip
301 top side
302 underside
310 first electrical contact
320 second electrical contact
330 mesa
340 edge region
350 slag burr
400 through contact
401 top side
402 underside
500 protective diode
501 top side
600 wavelength-converting material

### DETAILED DESCRIPTION

Our optoelectronic component comprises a composite body comprising a molded body and an optoelectronic semiconductor chip embedded into the molded body. An electrically conductive through contact extends from a top side of the composite body to an underside of the composite body through the molded body. A top side of the optoelectronic semiconductor chip is at least partly not covered by the molded body. The optoelectronic semiconductor chip comprises a first electrical contact on its top side. A first top side metallization is arranged on the top side of the composite body and electrically conductively connects the first electrical contact to the through contact. The optoelectronic component comprises an upper insulation layer extending over the first top side metallization. In addition, the optoelectronic component comprises a second top side metallization arranged above the upper insulation layer and is electrically insulated with respect to the first top side metallization by the upper insulation layer.

The second top side metallization arranged on the top side of the composite body of this optoelectronic component may form a reflective mirror layer that increases the reflectivity of the top side of the composite body of the optoelectronic component. As a result, absorption losses on the top side of the composite body are advantageously reduced as a result of which the optoelectronic component may comprise a high efficiency.

The second top side metallization arranged on the top side of the composite body of the optoelectronic component may additionally protect the material of the composite body of the optoelectronic component against excessive ageing, which may bring about an advantageous increase in the lifetime of the optoelectronic component. Other organic constituents of the optoelectronic component, for example, the upper insulation layer, may also be protected against excessive ageing by the second top side metallization.

The upper insulation layer may also extend over the top side of the optoelectronic semiconductor chip. This advantageously simplifies production of the upper insulation layer.

The upper insulation layer may extend over the entire top side of the composite body. Advantageously, the optoelectronic component may be produced particularly simply as a result.

The second top side metallization may extend over a part of the top side of the optoelectronic semiconductor chip. By way of example, the second top side metallization may also extend over an edge of the top side of the optoelectronic semiconductor chip. As a result, reflectivity of the edge region of the top side of the optoelectronic semiconductor chip of the optoelectronic component is advantageously increased, as a result of which absorption losses may be reduced, which results in an increase in the efficiency of the optoelectronic component. Since the second top side metallization of the optoelectronic component is electrically insulated with respect to the first top side metallization of the optoelectronic component by the upper insulation layer, it is harmless if the second top side metallization electrically conductively connects to a second electrical contact of the optoelectronic semiconductor chip, for example, via a slag burr arranged in the edge region of the top side of the optoelectronic semiconductor chip.

The second top side metallization does not extend over an emission region on the top side of the optoelectronic semiconductor chip. Advantageously, as a result, an emission of electromagnetic radiation by the optoelectronic semiconductor chip of the optoelectronic component is not impaired by the second top side metallization.

A wavelength-converting material may be arranged in a region completely delimited by the second top side metallization on the top side of the composite body. The wavelength-converting material may, for example, convert electromagnetic radiation emitted by the optoelectronic semiconductor chip of the optoelectronic component at least partly into electromagnetic radiation of a different wavelength. The second top side metallization arranged on the top side of the composite body of the optoelectronic component may form a cavity in the region delimited by the second top side metallization, the cavity containing the wavelength-converting material. This advantageously results in a simple and compact construction of the optoelectronic component.

Above an edge region of the top side of the optoelectronic semiconductor chip a lower insulation layer may be arranged between the top side of the optoelectronic semiconductor chip and the first top side metallization. The lower insulation layer prevents formation of an electrically conductive connection between the first top side metallization and a second electrical contact of the optoelectronic semiconductor chip of the optoelectronic component, for example, as a result of a slag burr arranged in the edge region of the top side of the optoelectronic semiconductor chip. A short circuit between the first electrical contact and the second electrical contact of the optoelectronic semiconductor chip is prevented as a result.

A first underside metallization may be arranged on the underside of the composite body and electrically conductively connects to the through contact. Thus, the first underside metallization electrically conductively connects to the first electrical contact of the optoelectronic semiconductor chip of the optoelectronic component via the through contact and the first top side metallization. The first underside metallization may, for example, electrically contact the optoelectronic component.

An underside of the optoelectronic semiconductor chip may be at least partly exposed on the underside of the composite body. In this case, the optoelectronic semiconductor chip comprises a second electrical contact on its underside. As a result, the second electrical contact of the optoelectronic semiconductor chip on the underside of the composite body of the optoelectronic component is likewise exposed. This enables a first electrical contacting of the optoelectronic semiconductor chip of the optoelectronic component.

The second top side metallization may electrically conductively connect to the second electrical contact. By way of example, the second top side metallization may electrically conductively connect to the second electrical contact of the optoelectronic semiconductor chip via a slag burr arranged in an edge region of the top side of the optoelectronic semiconductor chip. Since the second top side metallization is electrically insulated with respect to the first top side metallization by the upper insulation layer, advantageously even in this case there is no short circuit between the first electrical contact and the second electrical contact of the optoelectronic semiconductor chip.

A second underside metallization may be arranged on the underside of the composite body and electrically conductively connect to the second electrical contact. The second underside metallization together with the first underside metallization enables electrical contacting of the optoelectronic component. The optoelectronic component may be provided, for example, as an SMT component for surface mounting, for example, for surface mounting by reflow soldering.

A protective diode may be embedded into the molded body. In this case, the first top side metallization electrically conductively connects to the protective diode. The protective diode may bring about a protection of the optoelectronic semiconductor chip of the optoelectronic component against damage as a result of electrostatic discharges. As a result of embedding the protective diode into the molded body of the optoelectronic component, it is advantageously not necessary to connect the optoelectronic component to an external protective diode.

The second underside metallization may electrically conductively connect to the protective diode. As a result, the protective diode may electrically connect in antiparallel with the optoelectronic semiconductor chip of the optoelectronic component.

Our method of producing an optoelectronic component comprises steps of providing an optoelectronic semiconductor chip comprising a first electrical contact on a top side, and for embedding the optoelectronic semiconductor chip into a molded body to form a composite body. In this case, the top side of the optoelectronic semiconductor chip is at least partly not covered by the molded body. The method comprises further steps of establishing an electrically conductive through contact extending from a top side of the composite body to an underside of the composite body through the molded body, establishing a first top side metallization on the top side of the composite body, the first top side metallization electrically conductively connecting the first electrical contact to the through contact, establishing an upper insulation layer extending over the first top side metallization, and establishing a second top side metallization above the upper insulation layer, the second top side metallization being electrically insulated with respect to the first top side metallization by the upper insulation layer.

This method makes it possible to produce an optoelectronic component with compact external dimensions. The second top side metallization established on the top side of the composite body of the optoelectronic component may be a mirror layer that increases reflectivity of the top side of the composite body. As a result, absorption losses on the top side of the composite body of the optoelectronic component are reduced as a result of which the optoelectronic component obtainable by the method may comprise a high efficiency.

The second top side metallization established on the top side of the composite body may additionally cover organic constituents of the optoelectronic component, for example, the composite body and thereby protect them against excessive ageing. As a result, the optoelectronic component obtainable by the method may advantageously comprise a high lifetime.

The upper insulation layer may be established in a manner extending over the entire top side of the composite body. Advantageously, the method is implementable particularly simply as a result.

The second top side metallization may be established such that it does not extend over an emission region on the top side of the optoelectronic semiconductor chip. Advantageously, as a result, the second top side metallization does not obstruct an emission of electromagnetic radiation by the optoelectronic semiconductor chip of the optoelectronic component obtainable by the method.

To establish the second top side metallization, steps may be carried out to arrange a layer of a photoresist on the upper insulation layer, operate the optoelectronic semiconductor chip to expose a portion of the layer of the photoresist, remove a part of the photoresist to uncover a portion of the upper insulation layer, wherein the exposed portion of the layer of the photoresist remains on the upper insulation layer, establish a metal layer on the layer of the photoresist and the uncovered portion of the upper insulation layer, and remove the layer of the photoresist and the portions of the metal layer arranged on the layer of the photoresist. This method makes it possible to establish the second top side metallization with a cutout aligned precisely with the emission region on the top side of the optoelectronic semiconductor chip. In this case, the precise alignment is advantageously automatically achieved by using the optoelectronic semiconductor chip for the exposure of the layer of the photoresist. As a result, advantageously, further complex measures for alignment are not required.

The method may comprise a further step of arranging a wavelength-converting material in a region completely delimited by the second top side metallization on the top side of the composite body. In this case, the wavelength-converting material may convert electromagnetic radiation emitted by the optoelectronic semiconductor chip of the optoelectronic component obtainable by the method at least partly into electromagnetic radiation of a different wavelength. This may, for example, generate light comprising a white color impression. Arrangement of the wavelength-converting material in the region completely delimited by the second top side metallization is advantageously implementable simply and cost-effectively and makes it possible to produce an optoelectronic component comprising compact external dimensions. Since it is possible to align the region completely delimited by the second top side metallization on the top side of the composite body precisely with the radiation emission face on the top side of the optoelectronic semiconductor chip, in this method the wavelength-converting material arranged in the delimited region is also precisely aligned with the radiation emission region on the top side of the optoelectronic semiconductor chip.

Before establishing the first top side metallization, a further step may be carried out to arrange a lower insulation layer above an edge region of the top side of the optoelectronic semiconductor chip. In this case, the lower insulation layer may cover slag burrs that are possibly present in the edge region of the top side of the optoelectronic semiconductor chip and electrically connected to a second electrical contact of the optoelectronic semiconductor chip. By arranging the lower insulation layer, this makes it possible to prevent formation of an electrically conductive connection between the first top side metallization and the second electrical contact of the optoelectronic semiconductor chip, as a result of which a short circuit between the first electrical contact and the second electrical contact of the optoelectronic semiconductor chip is also avoided.

The through contact may be jointly embedded with the optoelectronic semiconductor chip into the molded body. In this case, the material of the molded body may be simultaneously molded around the through contact and the optoelectronic semiconductor chip. Advantageously, this enables a simple and cost-effective implementation of the method.

The above-described properties, features and advantages and the way in which they are achieved will become clearer and more clearly understood in association with the following description of examples explained in greater detail in association with the drawings.

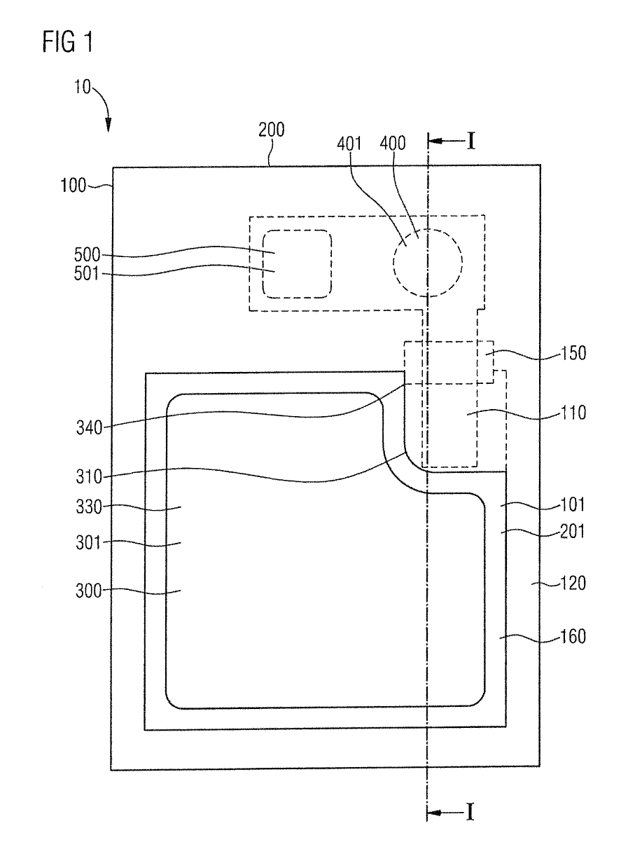

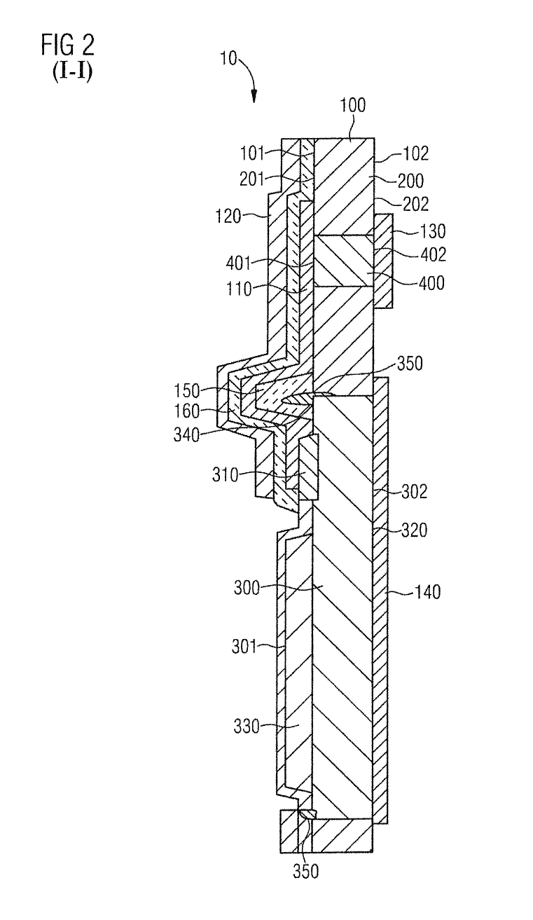

FIG. 1 shows a schematic and partly transparently illustrated plan view of a first optoelectronic component 10. FIG. 2 shows a schematic sectional side view of the first optoelectronic component 10, wherein the first optoelectronic component 10 is cut on a sectional plane I-I depicted in FIG. 1. The first optoelectronic component 10 may be, for example, a light emitting diode component (LED component) provided to emit electromagnetic radiation, for example, visible light.

The first optoelectronic component 10 comprises a composite body 100. The composite body 100 is formed by a molded body 200 into which an optoelectronic semiconductor chip 300, a through contact 400 and a protective diode 500 are embedded.

The molded body 200 comprises an electrically insulating molding material. The molding material may comprise, for example, an epoxy resin and/or a silicone. The molded body 200 may also be referred to as mold body and is preferably produced by a molding method (mold method), for example, by compression molding or transfer molding, in particular, for example, by foil-assisted transfer molding. The optoelectronic semiconductor chip 300, the through contact 400 and the protective diode 500 are preferably embedded into the molded body 200 already during production of the molded body 200, by the material of the molded body 200 being molded around the optoelectronic semiconductor chip 300, the through contact 400 and the protective diode 500.

A top side 301 of the optoelectronic semiconductor chip 300, a top side 401 of the through contact 400 and a top side 501 of the protective diode 500 are each at least partly not covered by the material of the molded body 200, but rather are at least partly exposed on a top side 201 of the molded body 200. Preferably, the top side 301 of the optoelectronic semiconductor chip 300, the top side 401 of the through contact 400 and the top side 501 of the protective diode 500 terminate substantially flush with the top side 201 of the molded body 200. The top side 201 of the molded body 200, the top side 301 of the optoelectronic semiconductor chip 300, the top side 401 of the through contact 400 and the top side 501 of the protective diode 500 jointly form a top side 101 of the composite body 100.

An underside 302 of the optoelectronic semiconductor chip 300 located opposite the top side 301 of the optoelectronic semiconductor chip 300, an underside 402 of the through contact 400 located opposite the top side 401 of the through contact 400 and an underside of the protective diode 500 located opposite the top side 501 of the protective diode 500 are also at least partly not covered by the material of the molded body 200. As a result, the underside 302 of the optoelectronic semiconductor chip 300, the underside 402 of the through contact 400 and the underside of the protective diode 500 are at least partly exposed on an underside 202 of the molded body 200 located opposite the top side 201 of the molded body 200. Preferably, the underside 302 of the optoelectronic semiconductor chip 300, the underside 402 of the through contact 400 and the underside of the protective diode 500 terminate substantially flush with the underside 202 of the molded body 200. The underside 202 of the molded body 200, the underside 302 of the optoelectronic semiconductor chip 300, the underside 402 of the through contact 400 and the underside of the protective diode 500 jointly form an underside 102 of the composite body 100.

The optoelectronic semiconductor chip 300 may be, for example, a light emitting diode chip (LED chip) and is configured to emit electromagnetic radiation, for example, visible light. The optoelectronic semiconductor chip 300 comprises a mesa 330 on its top side 301, electromagnetic radiation being emitted at the mesa during operation of the optoelectronic semiconductor chip 300. The region of the mesa on the top side 301 of the optoelectronic semiconductor chip 300 thus forms a radiation emission face of the optoelectronic semiconductor chip 300.

On its top side 301, the optoelectronic semiconductor chip 300 comprises a first electrical contact 310. On its underside 302, the optoelectronic semiconductor chip 300 comprises a second electrical contact 320. Via the first electrical contact 310 and the second electrical contact 320, an electrical voltage may be applied to the optoelectronic semiconductor chip 300 and an electrical current may be conducted through the optoelectronic semiconductor chip 300 to cause the optoelectronic semiconductor chip 300 to emit electromagnetic radiation.

The optoelectronic semiconductor chip 300 comprises sidewalls extending from the top side 301 to the underside 302 of the optoelectronic semiconductor chip 300. In an edge region 340 between the top side 301 and the sidewalls of the optoelectronic semiconductor chip 300, the optoelectronic semiconductor chip 300 may comprise production-dictated slag burrs 350 that electrically conductively connect to the second electrical contact 320 on the underside 302 of the optoelectronic semiconductor chip 300 and may rise above the top side 301 of the optoelectronic semiconductor chip 300, for example, by up to 20 μm in a direction perpendicular to the top side 301. In this case, formation of electrically conductive connections between the slag burrs 350 and the first electrical contact 310 of the optoelectronic semiconductor chip 300 must be avoided to avoid a short circuit between the first electrical contact 310 and the second electrical contact 320 of the optoelectronic semiconductor chip 300.

The through contact 400 comprises an electrically conductive material, for example, a metal or a doped semiconductor material. There is an electrically conductive connection between the top side 401 and the underside 402 of the through contact 400. As a result, the through contact 400 forms an electrically conductive connection (extending through the molded body 200) between the top side 101 of the composite body 100 and the underside 102 of the composite body 100.

Instead of the through contact 400 already being embedded into the molded body 200 jointly with the optoelectronic semiconductor chip 300 and the protective diode 500 during the formation of the molded body 200, it is also possible to establish the through contact 400 only after the formation of the molded body 200, by firstly establishing an opening extending from the top side 201 of the molded body 200 to the underside 202 of the molded body 200 through the molded body 200 and subsequently filling the opening with an electrically conductive material.

The protective diode 500 protects the optoelectronic semiconductor chip 300 of the optoelectronic component 10 against damage as a result of electrostatic discharges. For this purpose, the protective diode 500 connects in antiparallel with the optoelectronic semiconductor chip 300 in the first optoelectronic component 10 in the manner explained in even greater detail below. The protective diode 500 may be omitted in a simplified construction.

A lower insulation layer 150 is arranged on the top side 101 of the composite body 100. The lower insulation layer 150 comprises an electrically insulating material. The lower insulation layer 150 extends over a portion of the top side 301 of the optoelectronic semiconductor chip 300 in the edge region 340 of the top side 301 and over a portion of the top side 201 of the molded body 200 that adjoins the aforementioned portion. In this case, the lower insulation layer 150 is arranged in a part of the top side 101 of the composite body 100 situated between the first electrical contact 310 of the optoelectronic semiconductor chip 300 and the top side 401 of the through contact 400. In a direction dimensioned perpendicularly to the top side 101 of the composite body 100, the lower insulation layer 150 comprises a thickness large enough to ensure that slag burrs 350 covered by the lower insulation layer 150 are completely covered by the lower insulation layer 150.

Establishing and patterning the lower insulation layer 150 on the top side 101 of the composite body 100 may be carried out, for example, by a mask-lithographic method.

A first top side metallization 110 is arranged on a partial region of the top side 101 of the composite body 100 of the first optoelectronic component 10. The first top side metallization 110 comprises an electrically conductive material and forms an electrically conductive connection between the first electrical contact 310 on the top side 301 of the optoelectronic semiconductor chip 300, the top side 401 of the through contact 400 and the top side 501 of the protective diode 500. In this case, the first top side metallization 110 extends in the region between the first electrical contact 310 of the optoelectronic semiconductor chip 300 and the top side 401 of the through contact 400 over the lower insulation layer 150. As a result, the lower insulation layer 150 electrically insulates the first top side metallization 110 with respect to possible slag burrs 350 in the edge region 340 of the top side 301 of the optoelectronic semiconductor chip 300 and thus also with respect to the second electrical contact 320 of the optoelectronic semiconductor chip 300.

Establishing and patterning the first top side metallization 110 may be carried out, for example, by a mask-lithographic method. The first top side metallization 110 is established after the lower insulation layer 150 has been established.

The first optoelectronic component 10 comprises an upper insulation layer 160 extending over the first top side metallization 110 and, in the example illustrated, also over the portions of the lower insulation layer 150 not covered by the first top side metallization 110, and over all portions of the top side 101 of the composite body 100 not covered by the lower insulation layer 150 or the first top side metallization 110. In particular, the upper insulation layer 160 may also extend over the radiation emission face in the region of the mesa 330 on the top side 301 of the optoelectronic semiconductor chip 300. However, this is not absolutely necessary. All that is essential is that the upper insulation layer 160 completely covers the first top side metallization 110. Parts of the top side 101 of the composite body 100 may optionally remain uncovered.

The upper insulation layer 160 comprises an electrically insulating material. If the upper insulation layer 160 covers the radiation emission face of the optoelectronic semiconductor chip 300 in the region of the mesa 330 on the top side 301 of the optoelectronic semiconductor chip 300, then the upper insulation layer 160 is optically transparent to electromagnetic radiation emitted by the optoelectronic semiconductor chip 300. The upper insulation layer 160 may comprise, for example, SiOₓ, Al₂O₃, Ta₂O₅, an Ormocer or a silicone.

The upper insulation layer 160 is established after the first top side metallization 110 has been established in production of the first optoelectronic component 10.

A second top side metallization 120 is arranged above the upper insulation layer 160 of the first optoelectronic component 10. The second top side metallization 120 comprises an electrically conductive material, which is preferably optically highly reflective.

The second top side metallization 120 extends over a large part of the upper insulation layer 160. In this case, the second top side metallization 120 may also extend over a region arranged above the edge region 340 of the top side 301 of the optoelectronic semiconductor chip 300. However, the second top side metallization 120 does not extend over the radiation emission face in the region of the mesa 330 on the top side 301 of the optoelectronic semiconductor chip 300. Preferably, the second top side metallization 120 completely delimits the radiation emission region on the top side 301 of the optoelectronic semiconductor chip 300.

The second top side metallization 120 is electrically insulated with respect to the first top side metallization 110 by the upper insulation layer 160. The second top side metallization 120 may electrically conductively connect to the second electrical contact 320 of the optoelectronic semiconductor chip 300 via the slag burrs 350 arranged in the edge region 160 of the top side 301 of the optoelectronic semiconductor chip 300. However, the slag burrs 350 in the edge region 340 of the top side 301 of the optoelectronic semiconductor chip 300 may also be insulated with respect to the second top side metallization 120 by the upper insulation layer 160.

The second top side metallization 120 may be arranged above the upper insulation layer 160 and patterned, for example, by a lithographic method. In particular, the second top side metallization 120 may be established, for example, by a mask lithography method. Alternatively, the second top side metallization 120 may be established by a lithographic method in which a photoresist is directly exposed by a laser. The second top side metallization 120 may alternatively or additionally be applied or thickened by an electrolytic method. In this case, the second top side metallization 120 may additionally be encapsulated with a further metal comprising good optical reflection properties. This encapsulation may be carried out, for example, by electroless deposition of the encapsulation metal.

The second top side metallization forms a mirror that increases reflectivity of the top side of the first optoelectronic component 10. Electromagnetic radiation emitted by the optoelectronic semiconductor chip 300 of the first optoelectronic component 10 and backscattered in the direction toward the top side 101 of the composite body 100 of the first optoelectronic component 10 may be reflected at the second top side metallization 120 instead of being absorbed on the top side 101 of the composite body 100. As a result, an efficiency of the first optoelectronic component 10 may increase.

The second top side metallization 120 covers a large part of the organic materials on the top side 101 of the composite body 100, in particular the top side 201 of the molded body 200. As a result, the second top side metallization 120 may prevent excessive ageing of the organic materials of the composite body 100 of the first optoelectronic component 10, which may increase a lifetime of the first optoelectronic component 10.

A first underside metallization 130 is arranged on the underside 102 of the composite body 100 of the first optoelectronic component 10. The first underside metallization 130 extends over the underside 402 of the through contact 400 and electrically conductively connects to the through contact 400. Thus, via the through contact 400 and the first top side metallization 110 there is an electrically conductive connection between the first underside metallization 130 and the first electrical contact 310 of the optoelectronic semiconductor chip 300.

In addition, a second underside metallization 140 is arranged on the underside 102 of the composite body 100 of the optoelectronic component 10. The second underside metallization 140 extends over the underside 302 of the optoelectronic semiconductor chip 300 and electrically conductively connects to the second electrical contact 320 on the underside 302 of the optoelectronic semiconductor chip 300. In addition, the second underside metallization 140 extends over the underside of the protective diode 500 and electrically conductively connects to the underside of the protective diode 500. As a result, the protective diode 500 electrically connects in antiparallel with the optoelectronic semiconductor chip 300.

The first underside metallization 130 and the second underside metallization 140 may be established, for example, by a mask lithography method. In this case, the first underside metallization 130 and the second underside metallization 140 may be established jointly or successively in an arbitrary order. The first underside metallization 130 and the second underside metallization 140 may be established before or after establishing the lower insulation layer 150, the first top side metallization 110, the upper insulation layer 160 and the second top side metallization 120.

The first underside metallization 130 and the second underside metallization 140 may serve as electrical contacts of the first optoelectronic component 10. The first optoelectronic component 10 may be provided, for example, as an SMT component for surface mounting, for example, for surface mounting by reflow soldering.

The first optoelectronic component 10 may be produced jointly with a plurality of first optoelectronic components 10 of identical type in a panel assemblage in common work processes. For this purpose, a plurality of optoelectronic semiconductor chips 300, through contacts 400 and protective diodes 500 are embedded into a common large molded body. Arranging the lower insulation layer 150, the first top side metallization 110, the upper insulation layer 160, the second top side metallization 120 and the underside metallizations 130, 140 for each set of an optoelectronic semiconductor chip 300, a through contact 400 and a protective diode 500 is carried out in parallel in common processing steps. It is only upon conclusion of processing that the panel assemblage is divided to singulate the composite bodies 100 of the individual first optoelectronic components 10.

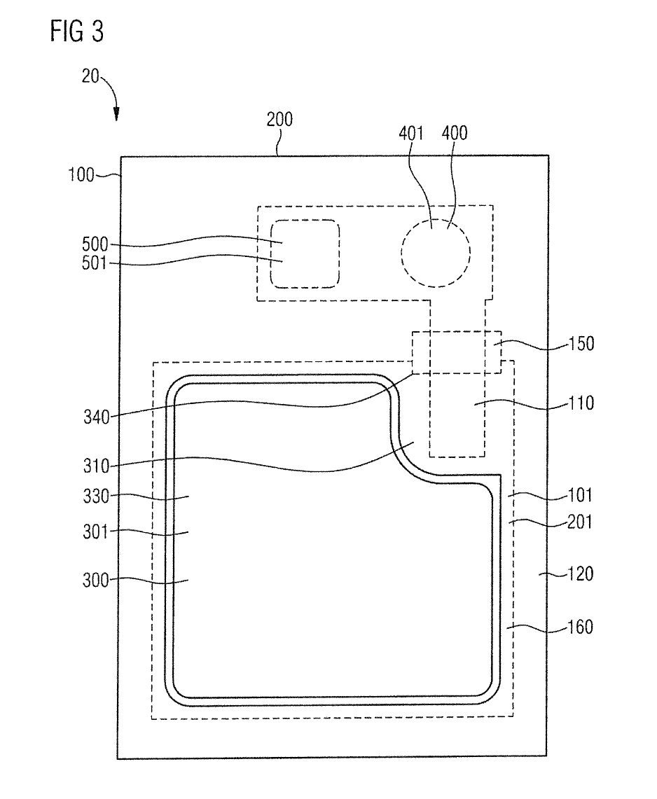

FIG. 3 shows a schematic plan view of a second optoelectronic component 20. The second optoelectronic component 20 corresponds, apart from the differences described below, to the first optoelectronic component 10 in FIGS. 1 and 2. Therefore, corresponding component parts are provided with the same reference signs in FIG. 3 as in FIGS. 1 and 2. The second optoelectronic component 20 may be produced by the production method explained above with reference to FIGS. 1 and 2, provided that the differences and special features described below are taken into account.

The second optoelectronic component 20 differs from the first optoelectronic component 10 in that the second top side metallization 120 in the second optoelectronic component 20 extends directly as far as the mesa 330 forming the radiation emission face of the optoelectronic semiconductor chip 300 on the top side 301 of the optoelectronic semiconductor chip 300. As a result, the second optoelectronic component 20 comprises on its top side particularly few surface areas configured such that they are neither light emitting nor reflective. As a result, in the case of the second optoelectronic component 20, during operation only particularly low absorption losses occur as a result of absorption of electromagnetic radiation on the top side of the second optoelectronic component 20.

In production of the second optoelectronic component 20, arranging the second top side metallization 120 may be carried out after establishing the upper insulation layer 160, in the manner explained below:

First, a layer of a photoresist is arranged on the upper insulation layer 160. The optoelectronic semiconductor chip 300 of the second optoelectronic component 20 is subsequently operated such that the optoelectronic semiconductor chip 300 emits electromagnetic radiation at its radiation emission face in the region of the mesa 330 on the top side 301. A portion of the layer of the photoresist arranged above the radiation emission face of the optoelectronic semiconductor chip 300 is exposed by the electromagnetic radiation. In contrast, the other regions of the layer of the photoresist arranged on the upper insulation layer 160 remain unexposed.

In a subsequent processing step, the unexposed parts of the layer of the photoresist are removed, while the exposed portion of the layer of the photoresist above the radiation emission face of the optoelectronic semiconductor chip 300 remains on the upper insulation layer 160.

A metal layer is then deposited on the residual remnants of the layer of the photoresist and on the uncovered portions of the upper insulation layer 160. Finally, the residual portion of the layer of the photoresist and the parts of the metal layer arranged thereon are removed in a liftoff process. The parts of the metal layer remaining on the upper insulation layer 160 then form the second top side metallization 120.

Since, in the method described, exposure of the layer of the photoresist is carried out by electromagnetic radiation emitted by the optoelectronic semiconductor chip 300 at the radiation emission face thereof, the method described results in an automatic precise alignment of the cutout in the second top side metallization 120 with the radiation emission face of the optoelectronic semiconductor chip 300.

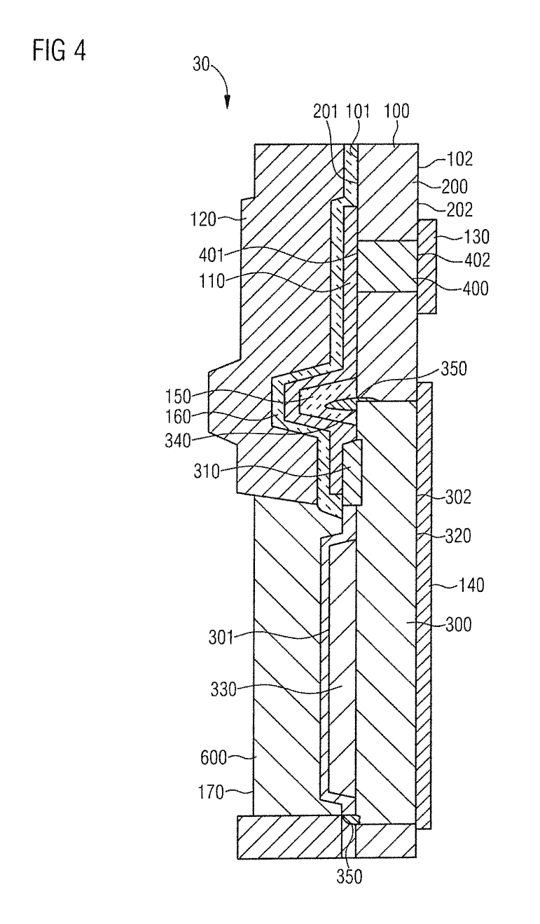

FIG. 4 shows a schematic sectional side view of a third optoelectronic component 30. The third optoelectronic component 30 corresponds in large part to the first optoelectronic component 10 in FIGS. 1 and 2 and to the second optoelectronic component 20 in FIG. 3. Corresponding component parts are provided with the same reference signs in FIG. 4 as in FIGS. 1 to 3. The third optoelectronic component 30 may be produced according to the method of producing the first optoelectronic component 10 as explained with reference to FIGS. 1 and 2, or according to the method of producing the second optoelectronic component 20 as explained with reference to FIG. 3, wherein the special features explained below should be taken into consideration.

In the third optoelectronic component 30, the second top side metallization 120 is formed with a large thickness in a direction perpendicular to the top side 101 of the composite body 100. This may be achieved, for example, by an electrolytic production or thickening of the second top side metallization 120.

The second top side metallization 120 comprises a cutout in the region of the radiation emission face of the optoelectronic semiconductor chip 300. In this case, the second top side metallization 120 completely delimits the radiation emission face of the optoelectronic semiconductor chip 300. The second top side metallization 120 thus completely encloses a delimited region 170 in which the radiation emission face is arranged in the region of the mesa 330 on the top side 301 of the optoelectronic semiconductor chip 300. The second top side metallization 120 forms a reflector which encloses the delimited region 170 and which may bring about a focusing of the electromagnetic radiation emitted by the optoelectronic semiconductor chip 300.

A wavelength-converting material 600 is arranged in the region 170 completely delimited by the second top side metallization 120 on the top side 101 of the composite body 100. The wavelength-converting material 600 may comprise, for example, a matrix material and wavelength-converting particles embedded into the matrix material. The matrix material may comprise a silicone, for example. The wavelength-converting material 600 may have been arranged in the delimited region 170 by a metering method, for example.

The wavelength-converting material 600 converts electromagnetic radiation emitted by the optoelectronic semiconductor chip 300 at least partly into electromagnetic radiation of a different wavelength. By way of example, the wavelength-converting material 600 may be configured to convert electromagnetic radiation comprising a wavelength from the blue or ultraviolet spectral range into electromagnetic radiation comprising a wavelength from the yellow spectral range. A mixture of converted and unconverted electromagnetic radiation may comprise a white color impression, for example.

Our components and methods been illustrated and described in greater detail on the basis of the preferred examples. Nevertheless, this disclosure is not restricted to the examples disclosed. Rather, other variations may be derived therefrom by those skilled in the art, without departing from the scope of protection of the appended claims.

This application claims priority of DE 10 2014 116 079.7, the subject matter of which is incorporated herein by reference.

1-20. (canceled)

21. An optoelectronic component comprising:
a composite body comprising a molded body; and
an optoelectronic semiconductor chip embedded into the molded body,
wherein an electrically conductive through contact extends from a top side of the composite body to an underside of the composite body through the molded body,
a top side of the optoelectronic semiconductor chip is at least partly not covered by the molded body,
the optoelectronic semiconductor chip comprises a first electrical contact on its top side,
a first top side metallization is arranged on the top side of the composite body and electrically conductively connects the first electrical contact to the through contact,
the optoelectronic component comprises an upper insulation layer extending over the first top side metallization, and
the optoelectronic component comprises a second top side metallization arranged above the upper insulation layer and electrically insulated with respect to the first top side metallization by the upper insulation layer.

22. The optoelectronic component according to claim 21, wherein the upper insulation layer also extends over the top side of the optoelectronic semiconductor chip.

23. The optoelectronic component according to claim 22, wherein the upper insulation layer extends over the entire top side of the composite body.

24. The optoelectronic component according to claim 21, wherein the second top side metallization extends over a part of the top side of the optoelectronic semiconductor chip.

25. The optoelectronic component according to claim 21, wherein the second top side metallization does not extend over an emission region on the top side of the optoelectronic semiconductor chip.

26. The optoelectronic component according to claim 25, wherein a wavelength-converting material is arranged in a region completely delimited by the second top side metallization on the top side of the composite body.

27. The optoelectronic component according to claim 21, wherein, above an edge region of the top side of the optoelectronic semiconductor chip, a lower insulation layer is arranged between the top side of the optoelectronic semiconductor chip and the first top side metallization.

28. The optoelectronic component according to claim 21, wherein a first underside metallization is arranged on the underside of the composite body and electrically conductively connects to the through contact.

29. The optoelectronic component according to claim 21, wherein an underside of the optoelectronic semiconductor chip is at least partly exposed on the underside of the composite body, and
the optoelectronic semiconductor chip comprises a second electrical contact on its underside.

30. The optoelectronic component according to claim 29, wherein the second top side metallization electrically conductively connects to the second electrical contact.

31. The optoelectronic component according to claim 29, wherein a second underside metallization is arranged on the underside of the composite body and electrically conductively connects to the second electrical contact.

32. The optoelectronic component according to claim 21, wherein a protective diode is embedded into the molded body, and
the first top side metallization electrically conductively connects to the protective diode.

33. The optoelectronic component according to claim 31, wherein the second underside metallization electrically conductively connects to the protective diode.

34. A method of producing an optoelectronic component comprising:
providing an optoelectronic semiconductor chip comprising a first electrical contact on a top side;
embedding the optoelectronic semiconductor chip into a molded body to form a composite body,
wherein the top side of the optoelectronic semiconductor chip is at least partly not covered by the molded body;
establishing an electrically conductive through contact extending from a top side of the composite body to an underside of the composite body through the molded body;
establishing a first top side metallization on the top side of the composite body, said first top side metallization electrically conductively connecting the first electrical contact to the through contact;
establishing an upper insulation layer extending over the first top side metallization; and
establishing a second top side metallization above the upper insulation layer, said second top side metallization being electrically insulated with respect to the first top side metallization by the upper insulation layer.

35. The method according to claim 34, wherein the upper insulation layer is established in a manner extending over the entire top side of the composite body.

36. The method according to claim 34, wherein the second top side metallization is established such that it does not extend over an emission region on the top side of the optoelectronic semiconductor chip.

37. The method according to claim 36, further comprising:
arranging a layer of a photoresist on the upper insulation layer;
operating the optoelectronic semiconductor chip to expose a portion of the layer of the photoresist;
removing a part of the photoresist to uncover a portion of the upper insulation layer, wherein the exposed portion of the layer of the photoresist remains on the upper insulation layer;
establishing a metal layer on the layer of the photoresist and the uncovered portion of the upper insulation layer; and
removing the layer of the photoresist and the portions of the metal layer arranged on the layer of the photoresist,
to establish the second top side metallization.

38. The method according to claim 36, further comprising:
arranging a wavelength-converting material in a region completely delimited by the second top side metallization on the top side of the composite body.

39. The method according to claim 34, wherein, before establishing the first top side metallization,
arranging a lower insulation layer above an edge region of the top side of the optoelectronic semiconductor chip.

40. The method according to claim 34, wherein the through contact is embedded jointly with the optoelectronic semiconductor chip into the molded body.
